(19) United States
(12) Patent Application Publication
(10) Pub. No.: US 2012/0279771 A1
(43) Pub. Date: Nov. 8, 2012

(54) PACKAGE STRUCTURE WITH ELECTRONIC COMPONENT AND METHOD FOR MANUFACTURING SAME

(75) Inventor: JUN-YI XIAO, Zhongshan City (CN)

(73) Assignees: HON HAI PRECISION INDUSTRY CO., LTD., Tu-Cheng (TW); AMBIT MICROSYSTEMS (ZHONGSHAN) LTD., Zhongshan City (CN)

(21) Appl. No.: 13/160,514

(22) Filed: Jun. 15, 2011

(30) Foreign Application Priority Data
May 5, 2011 (CN) 201110115610.2

(51) Int. Cl. H05K 1/18; H05K 3/36

(52) U.S. Cl. 174/260; 29/830

(57) ABSTRACT

A package structure comprising a first substrate, a second substrate, an encapsulation layer sandwiched between the first and second substrates, and at least one electronic component mounted on the first substrate and isolated from the second substrate by the encapsulation layer. At least one conducting hole is defined in the encapsulation layer to communicate the at least one electronic component with the second substrate. An inner wall of each of the at least one conducting hole is coated with a first metal layer to electrically connect the at least one electronic component to the second substrate.

### BACKGROUND

1. Technical Field

The present disclosure generally relates to package structures with electronic components and methods manufacturing the same, more particularly to a package structure with an electronic component encapsulated between two substrates.

2. Description of Related Art

Generally, a package structure with electronic components (e.g. capacitors) includes a substrate having an opening. An electronic component is mounted in the opening and encapsulated with the substrate. However, it is difficult to reduce costs of the package structure due to complicated fabricating process involved in fabrication of the opening in the substrate. Furthermore, size of the electronic component is required to be smaller than the opening of the substrate to be received in the opening, therefore, the package structure cannot employ multifarious electronic components.

Therefore, a need exists in the industry to overcome the described problem.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of a package structure with electronic component of an exemplary embodiment of the disclosure.

FIG. 2A is a schematic view of fixing the electronic component on a first substrate.

FIG. 2B is a schematic view of encapsulating the electronic component and the first substrate of FIG. 2A to form an encapsulation layer.

FIG. 2C is a schematic view of fabricating at least one conducting hole in the encapsulation layer of FIG. 2B.

FIG. 2D is a schematic view of coating a fist metal layer on an inner wall of the at least one conducting hole FIG. 2C.

FIG. 2E is a schematic view of a second substrate mounted on structure of FIG. 2D.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

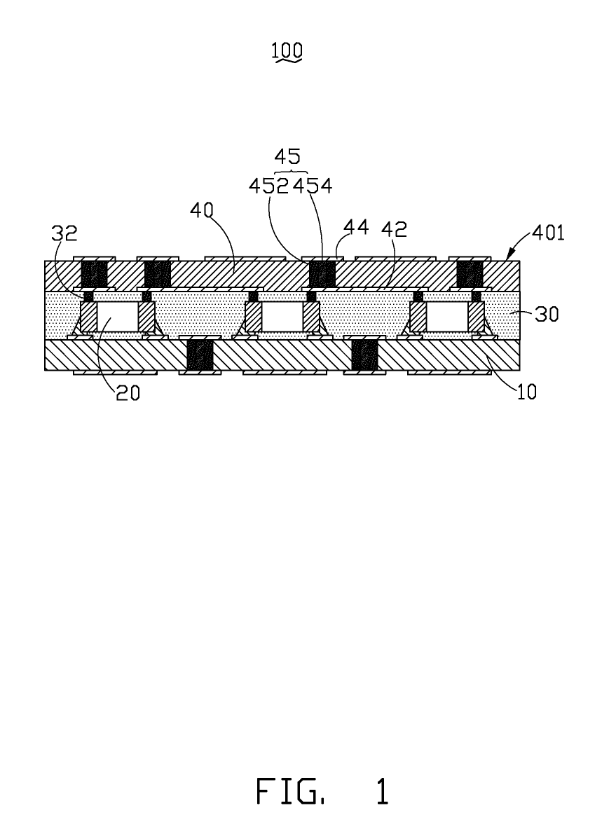

Referring to FIG. 1, a package structure 100 comprises a first substrate 10, an electronic component 20 configured and structured on the first substrate 10, an encapsulation layer 30 encapsulating the electronic component 20 to the first substrate 10, and a second substrate 40 configured on one side of the encapsulation layer 30 distal from the first substrate 10. The electronic component 20 is mounted on the first substrate 10 and isolated from the second substrate 40 by the encapsulation layer 30. That is, the encapsulation layer 30 is sandwiched between the first and second substrates 10, 40 and the electronic component 20 is mounted on the first substrate 10 and isolated from the second substrate 40 by the encapsulation layer 30.

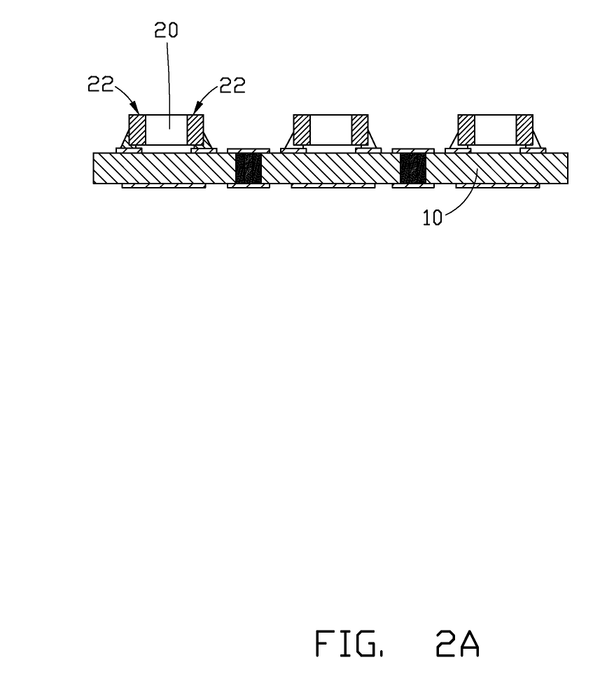

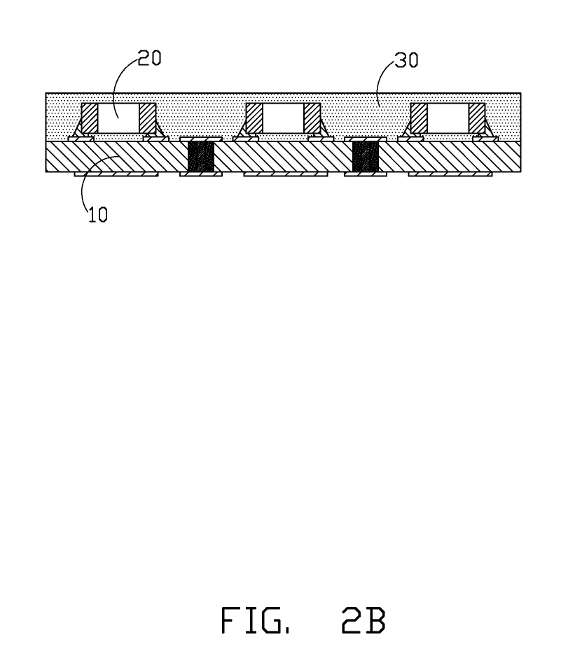

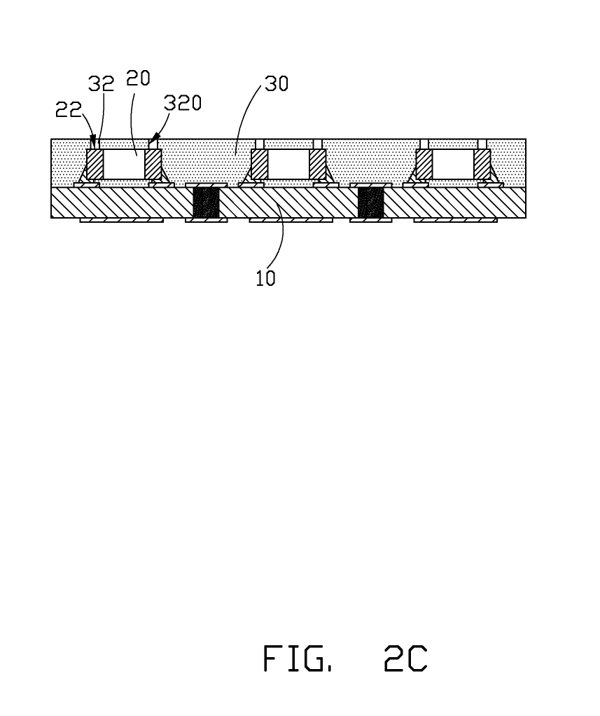

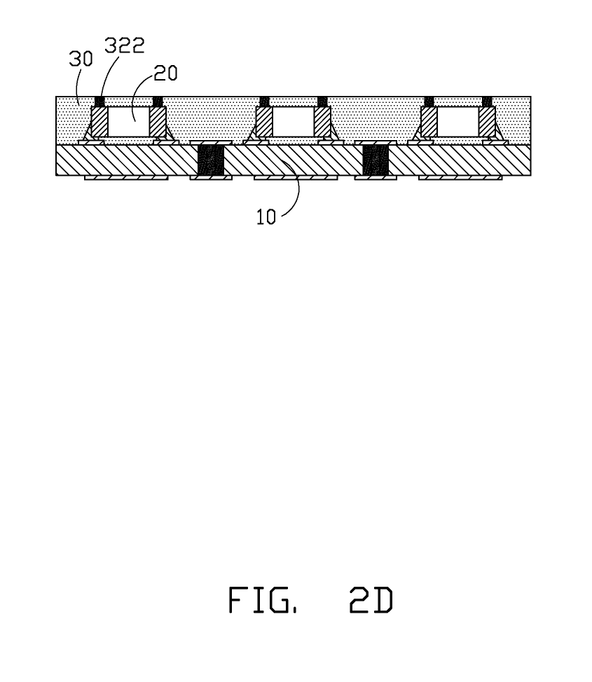

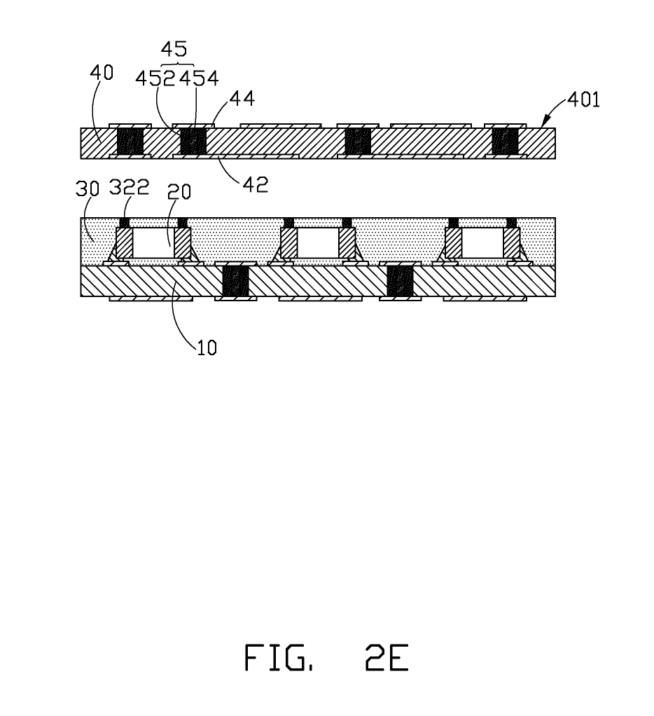

The encapsulation layer 30 defines at least one conducting hole 32 opposite to the second substrate 40 to electrically connect the electronic component 20 to the second substrate 40. In this embodiment, the second substrate 40 comprises a conductive layer 42. The electronic component 20 comprises a pair of electrodes 22 configured to face the conductive layer 42 of the second substrate 40 (shown in FIG. 2A). Referring to FIG. 2C and FIG. 2D, an inner wall 320 of the at least one conducting hole 32 is coated with a first metal layer 322 electrically connecting the electronic component 20 to the conductive layer 42. In this embodiment, the first metal layer 322 electrically connects to the electrodes 22 of the electronic component 20.

In summary, the electronic component 20 is encapsulated between the first substrate 10 and the second substrate 40 to form the package structure 100, bringing price reduction of the package structure 100 due to simplified fabricating process of the first and second substrate 10, 40. Furthermore, the package structure 100 can employ multifarious electronic components 20 with different sizes. In other embodiments, the package structure 100 comprises two or more electronic components 20.

In this embodiment, the second substrate 40 comprises a plurality of soldering pads 44 configured on a top surface 401 of the second substrate 40 away from the encapsulation layer 30 and electrically connecting to the conductive layer 42 via a plurality of holes 45 defined in the second substrate 40. An inner wall of each of the holes 45 is coated with a second metal layer 425 to electrically connect between the corresponding soldering pads 44 and the conductive layer 42. Each of the holes 45 is filled with an insulated materials 454 to provide secure connection between the soldering pads 44 and the second substrate 40, preventing the soldering pads 44 from falling off from the second substrate 40.

FIGS. 2A-2E are schematic views of a method for packaging the electronic component 20 in the package structure 100. The method used to package the electronic component 20 between the first substrate 10 and the second substrate 40 comprises steps as follow.

Referring to FIG. 2A, mounting the electronic component 20 on the first substrate 10. In this embodiment, the electronic component 20 comprises a pair of electrodes 22 and is soldered on the first substrate 10, and the pair of electrodes 22 are located away from the first substrate 10.

Referring to FIG. 2B, encapsulating the electronic component 20 on the first substrate 10 to form an encapsulation layer 30. In one embodiment, the encapsulation layer 30 is made from an epoxy resin and shaped like rectangular parallelepiped.

Referring to FIG. 2C and FIG. (d), fabricating at least one conducting hole 32 in the encapsulation layer 30, and the at least one conducting hole 32 electrically connects with the electronic component 20. An inner wall 320 of the at least one conducting hole 32 is coated with a first metal layer 322. In this embodiment, the conducting hole 32 is fabricated by drilling the encapsulation layer 30 perpendicular to the first substrate 10.

Referring to FIG. 2E, soldering the second substrate 40 on an opposite side of the encapsulation layer 30 relative to the first substrate 10, and making the at least one conducting hole 32 electrically connect the electronic component 20 to the second substrate 40. A conductive layer 42 is formed on the second substrate 40 and electrically connects to the electronic component 20. A plurality of soldering pads 44 is configured on a top surface 401 of the second substrate 40 away from the encapsulation layer 30. A plurality of holes 45 is defined in the second substrate 40 to electrically connect the solder pads 44 to the conductive layer 42. An inner wall of each of the holes 45 is coated with a second metal layer 425. Each of the holes 45 is filled with an insulated materials 454 to provide secure connection between the soldering pads 44 and the second substrate 40.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A package structure comprising a first substrate, a second substrate, and an encapsulation layer sandwiched between the first and second substrates, at least one electronic component mounted on the first substrate and isolated from the second substrate by the encapsulation layer, at least one conducting hole being defined in the encapsulation layer to communicate the at least one electronic component with the second substrate, an inner wall of the at least one conducting hole being coated with a first metal layer to electrically connect the at least one electronic component to the second substrate.

2. The package structure as claimed in claim 1, wherein each of the at least one electronic component comprises a pair of electrodes, the second substrate comprises a conductive layer, and the first metal layer electrically connects the corresponding electrodes to the conductive layer.

3. The package structure as claimed in claim 2, wherein the pair of electrodes of each of the at least one electronic component is configured to face the conductive layer of the second substrate.

4. The package structure as claimed in claim 2, wherein the second substrate comprises a plurality of soldering pads configured on one side of the second substrate away from the encapsulation layer and electrically connected to the conductive layer via a plurality of holes.

5. The package structure as claimed in claim 4, wherein an inner wall of each of the holes is coated with a second metal layer to electrically connect the corresponding soldering pads to the conductive layer.

6. The package structure as claimed in claim 5, wherein each of the holes is filled with insulated materials.

7. A package structure comprising a first substrate, an electronic component configured and structured on the first substrate, an encapsulation layer encapsulating the electronic component to the first substrate, and a second substrate configured on one side of the encapsulation layer distal from the first substrate, the encapsulation layer defining at least one conducting hole coated with a first metal layer electrically connecting the electronic component to the second substrate.

8. The package structure as claimed in claim 7, wherein the electronic component comprises a pair of electrodes, the second substrate comprises a conductive layer, wherein the first metal layer electrically connects the corresponding electrodes to the conductive layer.

9. The package structure as claimed in claim 8, wherein the pair of electrodes of the electronic component are configured to face the conductive layer of the second substrate.

10. The package structure as claimed in claim 9, wherein the second substrate comprises a plurality of soldering pads configured on a top surface of the second substrate away from the encapsulation and electrically connecting to the conductive layer via a plurality of holes.

11. The package structure as claimed in claim 10, wherein an inner wall of each of the holes is coated with a second metal layer to electrically connect the soldering pads to the conductive layer.

12. The package structure as claimed in claim 11, wherein each of the holes is filled with insulated materials.

13. A method to package an electronic component between a first substrate and a second substrate, the method comprising:
mounting the electronic component on the first substrate;
encapsulating the electronic component on the first substrate to form an encapsulation layer;
fabricating at least one conducting hole in the encapsulation layer, the at least one conducting hole electrically connecting with the electronic component;
soldering the second substrate on an opposite side of the encapsulation layer relative to the first substrate, and making the at least one conducting hole electrically connect the electronic component to the second substrate.

14. The method as claimed in claim 13, wherein an inner wall of the at least one conducting hole is coated with a first metal layer.

15. The method as claimed in claim 14, wherein the at least one conducting hole is fabricated by drilling the encapsulation perpendicularly to the first substrate.

16. The method as claimed in claim 13, wherein a conductive layer is formed on the second substrate and electrically connects to the electronic component, and a plurality of soldering pads is configured on the second substrate away from the encapsulation layer.

17. The method as claimed in claim 16, wherein a plurality of holes is defined in the second substrate, and an inner wall of each of the holes is coated with a second metal layer to electrically connect the solder pads to the conductive layer.

18. The method as claimed in claim 17, wherein each of the holes is filled with an insulated materials to provide secure connection between the soldering pads and the second substrate.
